(19) United States
(12) Patent Application Publication
(10) Pub. No.: US 2004/0072083 A1
(43) Pub. Date: Apr. 15, 2004

(54) Photomask for manufacturing semiconductor device

(75) Inventors: Kouichi Saitou, Gifu-ken (JP); Ryu Shimizu, Mizuho-shi (JP)

Correspondence Address: McDERMOTT, WILL & EMERY, 600 13th Street, N.W., Washington, DC, 20005-3096, US

(73) Assignee: SANYO ELECTRIC CO., LTD.

(21) Appl. No.: 10/648,236

(22) Filed: Aug. 27, 2003

(30) Foreign Application Priority Data
Aug. 29, 2002 (JP) 2002-250233

(51) Int. Cl. G03F 9/00; G03C 5/00

(52) U.S. Cl. 430/5; 430/311; 430/396; 430/22

(57) ABSTRACT

A photomask for use in photolithographic processing performed to manufacture a semiconductor device. The photomask includes four square regions, each having a mask pattern. The four mask patterns are used successively and re formed so that the photomask is used oriented in substantially the same direction.

### CROSS-REFERENCES TO RELATED APPLICATIONS

This application is based upon and claims the benefit of priority from prior Japanese Patent Application No. 2002-250233 filed on Aug. 29, 2002, the entire contents of which are incorporated herein by reference.

### BACKGROUND OF THE INVENTION

The present invention relates to a method for manufacturing a semiconductor device, and more particularly, to a photomask for use in lithography to manufacture a semiconductor device.

Due to the increasing level of integration in recent semiconductor devices, fine processing technology has become more important for the manufacturing of semiconductor devices. For example, in photolithography, a semiconductor circuit pattern of a photomask is transcribed on a sensitized agent layer, which is then developed to form a sensitized agent pattern. The sensitized agent pattern must especially be formed with high accuracy. As the level of integration of the semiconductor device increases, the minimum dimension of the semiconductor circuit pattern decreases. Thus, the pattern of the photomask must be formed with high accuracy. This increases the cost of the photomask. In conventional photolithography, the required number of photomasks is the same as the number of steps performed to expose (transcribe) a semiconductor circuit pattern. Accordingly, an increase in the cost of each photomask raises the manufacturing cost of a semiconductor device.

To lower the manufacturing cost of the photomask, it is desired that the same single photomask be used when more than one photolithography step are performed.

Referring to FIG. 1, Japanese Laid-Opened Patent Publication No. 5-313348 describes a procedure for manufacturing a semiconductor device with a single photomask 10. The photomask 10 includes sets of patterns, with each set having four pattern regions A, B, C, and D. Each of the pattern regions A, B, C, and D has a pattern used to form a predetermined layer of a semiconductor device. The photomask 10 is rotated 90 degrees at a time in the clockwise direction during photolithography so that four layers of the semiconductor device are processed with the single photomask 10. More specifically, in step 1, regions A of the photomask 10 are used to form corresponding circuit patterns. The photomask 10 is then rotated by 90 degrees. In step 2, regions B of the photomask 10 is used to form corresponding circuit patterns at the same positions for an upper layer. In the same manner, the photomask 10 is rotated to use regions C and D to form corresponding circuit patterns.

In comparison to a method that uses one photomask for each step, the photomask drastically decreases the number of photomasks required to manufacture the semiconductor device and reduces the photomask-related cost for manufacturing the semiconductor device.

When manufacturing a semiconductor device with the photomask 10 of FIG. 1, the portions of a semiconductor wafer that are usable are only those corresponding to the portions exposed in the first exposure step, that is, only the portions corresponding to those exposed by the sixteen regions A when forming the lowermost layer circuit. The portions corresponding to regions B, C, and D in the first exposure step cannot be used as the semiconductor device. Since three fourths of the entire semiconductor wafer area corresponds to regions B, C, and D, the effective area of the semiconductor wafer that can be used as the semiconductor device is relatively small.

### SUMMARY OF THE INVENTION

One aspect of the present invention is a photomask for use in a plurality of photolithography steps performed to manufacture a semiconductor device having a plurality of layers. The photomask includes a plurality of mask patterns, each used in an associated one of the photolithography steps and corresponding to an associated one of the layers. The mask patterns are arranged so that the photomask is always used oriented in substantially the same direction.

Another aspect of the present invention is a method for manufacturing a semiconductor device having a plurality of layers. The method includes providing a photomask including a plurality of mask patterns, with each mask pattern corresponding to a different layer of the semiconductor device to be manufactured, and performing photolithographic processing of each of the layers using the mask pattern of the photomask corresponding to that layer with the photomask arranged each time oriented in a direction that is substantially the same for each layer and exposing only the mask pattern for the layer for which photolithographic processing is currently being performed and covering the other mask patterns.

A further aspect of the present invention is a photomask for use in performing photolithographic processing to manufacture a semiconductor device having a plurality of layers. The photomask includes a plurality of rectangular regions arranged adjacent to one another, a plurality of mask patterns, each corresponding to an associated one of the layers; and a target pattern arranged in each rectangular region for aligning the photomask. Each target pattern is arranged in a predetermined area of the rectangular region, and the predetermined area is defined at substantially the same position in each of the rectangular regions.

A further aspect of the present invention is a method for manufacturing a semiconductor device using a photomask including a plurality of mask patterns having at least a first mask pattern and a second mask pattern. The method includes exposing the first pattern while covering the other patterns to transcribe the first mask pattern on a semiconductor wafer, linearly moving the photomask and the semiconductor relative to each other to align the second mask pattern with the semiconductor wafer, and exposing the second mask pattern while covering the other mask patterns to transcribe the second mask pattern on the semiconductor wafer.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a schematic plan view illustrating the procedures for manufacturing a semiconductor device with a prior art photomask;

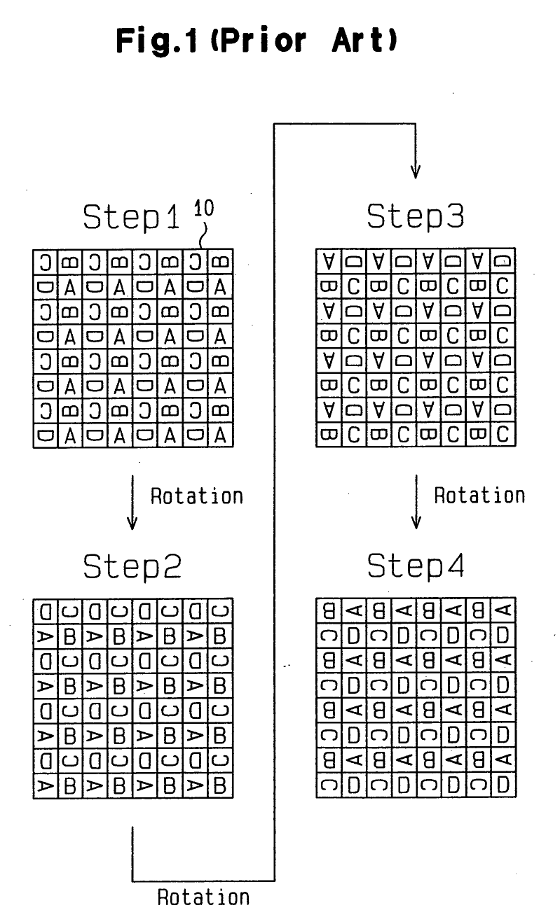

FIGS. 2A and 2B are plan views showing a photomask according to a preferred embodiment of the present invention; and

FIG. 3 is a schematic plan view illustrating the procedures for manufacturing a semiconductor device with the photomask of FIG. 2.

### DETAILED DESCRIPTION OF THE PREFERRED EMBODIMENTS

A semiconductor device photomask and a method for using the photomask according to a preferred embodiment of the present invention will now be discussed.

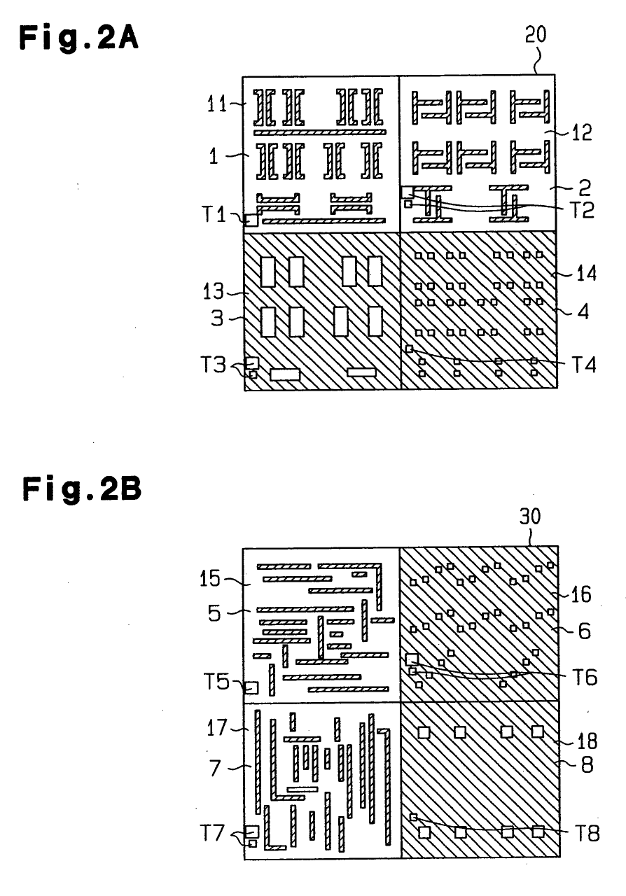

FIGS. 2A and 2B respectively show photomasks 20 and 30. The photomasks 20 and 30 have a plurality of mask patterns (processing patterns) 1, 2, 3, 4, 5, 6, 7, and 8 corresponding to a plurality of photolithography patterns of a semiconductor device. The mask patterns 1, 2, 3, and 4 are respectively formed in rectangular regions 11, 12, 13, and 14 of the photomasks 20. The mask patterns 5, 6, 7, and 8 are respectively formed in rectangular regions 15, 16, 17, and 18 of the photomask 30. The mask patterns of the photomasks 20 and 30 are successively used when performing lithography for multiple layers of the semiconductor device. Further, the mask patterns of the photomask 20 and the photomask 30 are arranged substantially in the same direction. More specifically, the upper ends of the rectangular regions 11 to 18 are directed to the same direction.

When the photolithography steps are divided into a former half and a latter half with four steps in each half, the mask patterns 1, 2, 3, and 4 of the photomask 20 are used successively in this order in the four steps of the former half. For example, the mask pattern 1 is used for a device partitioning step, the mask pattern 2 is used for a gate forming step, the mask pattern 3 is used for a transistor forming step, and the mask pattern 4 is used for a contact hole forming step. The photomask 20 is not rotated when proceeding to the next step and linearly moved along a horizontal plane.

The mask patterns 5, 6, 7, and 8 of the photomask 30 are used successively in this order in the four latter half photolithography steps. For example, the mask pattern 5 is used for a first wire forming step, the mask pattern 6 is used for a via hole forming step, the mask pattern 7 is used for a second wire forming step, and the mask pattern 8 is used for a pad forming step. The photomask 30 is not rotated when proceeding to the next step and linearly moved along a horizontal plane.

The rectangular regions 11 to 18 are arranged next to one another in the associated photomasks 20 and 30. It is preferred that at least one of the lengths, widths, and areas be substantially the same in the rectangular regions 11 to 18. It is further preferred that the rectangular regions 11 to 18 be squares. When the rectangular regions 11 to 18 are squares that are arranged next to each other, in each photomask 20 and 30, the mask pattern effective area is maximized and unused space is minimized.

Further, the mask patterns 1 to 8 are used oriented in the same direction during photolithography. More specifically, the photomasks 20 and 30 are arranged so that the same side of each rectangular region 11 to 18 faces the orientation flat of the wafer during transcription (exposure).

The regions 11 to 18 respectively include target patterns T1 to T8, which is used to form a target mark. The target mark functions as information used for positioning of the mask pattern in the following photolithography step. It is preferred that the target patterns T1 to T4 and T5 to T8 be formed in a certain area corresponding to regions 11 to 14 and 15 to 18, for example, near the left end or near the left corner.

An image recognizing mechanism, which is incorporated in an exposure apparatus, detects the shape and position of the target marks to recognize the mask pattern used in the next lithography step.

The method for using the photomasks 20 and 30, that is, the method for manufacturing a semiconductor device will now be discussed.

The photolithography process including the eight exposing and developing steps described below will now be described.

Step A: device partitioning step

Step B: gate forming step

Step C: transistor forming step

Step D: contact hole (first connection hole) forming step

Step E: first metal (wire) forming step

Step F: via hole (second connection hole) forming step

Step G: second metal (wire) forming step

Step H: pad forming step

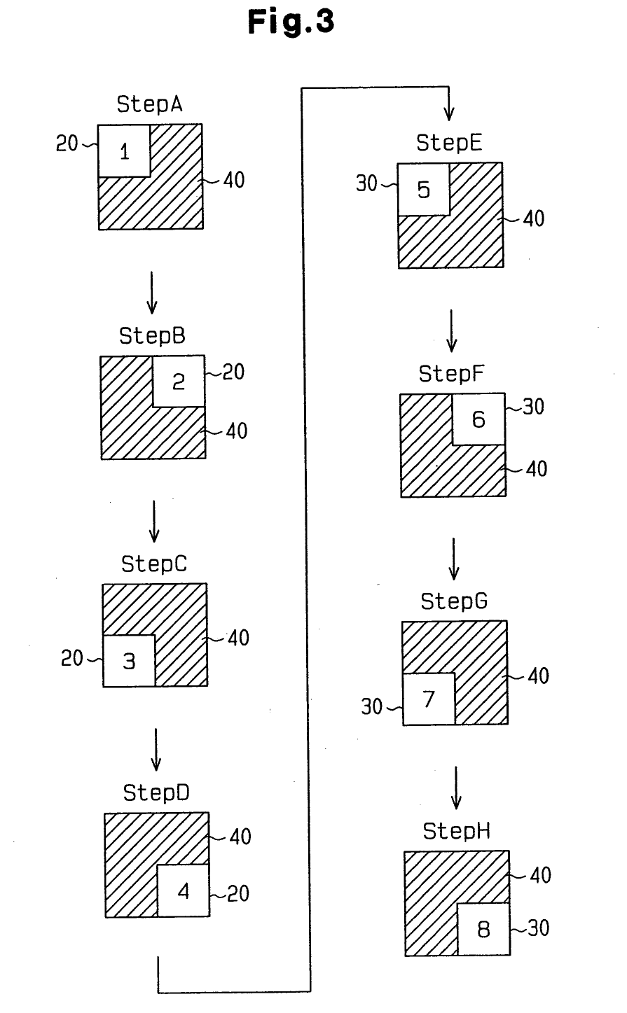

Steps A to D are the former half photolithography steps, and steps E to H are the latter half photolithography steps. When the eight steps A to H are performed, the photomasks 20 and 30 are used in the order shown in FIG. 3.

Among the mask patterns 1 to 8 of the photomasks 20 and 30, the mask patterns 1, 2, 5, and 7 are mainly line patterns used to pattern the wiring of the semiconductor device. The mask patterns 3, 4, 6, and 8 are mainly hole patterns used to pattern the connection holes of the semiconductor device. Accordingly, mask patterns mainly including line patterns and mask patterns mainly including hole patterns are mixed in each of the photomasks 20 and 30.

The mask pattern 1 of the photomask 20 shown in FIG. 2A is used during exposure in the device partitioning step (step A). More specifically, the photomask 20 is set on a mask holder of the exposure apparatus. The exposure apparatus has a blind 40. The blind 40 covers the mask patterns 2, 3, and 4, which are not used in this step and indicated by the cross-hatching lines, to selectively expose only the mask pattern 1 and form a pattern corresponding to the mask pattern 1. In this state, the target pattern T1, which is included in the mask pattern 1, forms a target mark on a sensitized layer. The target mark is aligned with the mask pattern 2 used in the next photolithography step.

Then, when exposure is performed during the gate forming step (step B), the mask pattern 2 of the photomask 20 is used. More specifically, the image recognizing mechanism of the exposure apparatus detects the target mark formed by the target pattern T1 and accordingly moves a wafer stage, which supports the wafer, in accordance with the detected information. This aligns the mask pattern 2, which is used in this step, with the wafer. The blind 40 covers the mask patterns 1, 3, and 4, which are not used in this step and indicated by the cross-hatching lines, to selectively expose only the mask pattern 2 and form a pattern corresponding to the mask pattern 2. In this state, the target pattern T2, which is included in the mask pattern 2, forms a target mark on the sensitized layer. The target mark is aligned with the mask pattern 3 used in the next photolithography step.

When exposure is performed during the transistor forming step (step C), the mask pattern 3 of the photomask 20 is used. The image recognizing mechanism detects the target mark formed by the target pattern T2 and accordingly moves the wafer stage to align the mask pattern 3 with the wafer. The blind 40 covers the mask patterns 1, 2, and 4, which are not used in this step and indicated by the crosshatching lines, to selectively expose only the mask pattern 3 and form a pattern corresponding to the mask pattern 3. In this state, the target pattern T3, which is included in the mask pattern 3, forms a target mark on the sensitized layer. The target mark is aligned with the mask pattern 4 used in the next photolithography step.

When exposure is performed during the contact hole forming step (step D), the mask pattern 4 of the photomask 20 is used. The image recognizing mechanism detects the target mark formed by the target pattern T3 and accordingly moves the wafer stage to align the mask pattern 4 with the wafer. The blind 40 covers the mask patterns 1, 2, and 3, which are not used in this step and indicated by the crosshatching lines, to selectively expose only the mask pattern 4 and form a pattern corresponding to the mask pattern 4. In this state, the target pattern T4, which is included in the mask pattern 4, forms a target mark on the sensitized layer. The target mark is aligned with the mask pattern 5 used in the next photolithography step.

When exposure is performed in the first metal forming step (step E), the mask pattern 5 of the photomask 30 is used. To do so, the photomask 20 held by the mask holder is replaced by the photomask 30.

Then, the image recognizing mechanism detects the target mark formed by the target pattern T4 and accordingly moves the wafer stage to align the mask pattern 5 with the wafer. The blind 40 covers the mask patterns 6, 7, and 8, which are not used in this step and indicated by the crosshatching lines, to selectively expose only the mask pattern 5 and form a pattern corresponding to the mask pattern 5. In this state, the target pattern T5, which is included in the mask pattern 5, forms a target mark on the sensitized layer. The target mark is aligned with the mask pattern 6 used in the next photolithography step.

When exposure is performed in the second via hole forming step (step F), the mask pattern 6 of the photomask 30 is used. The image recognizing mechanism detects the target mark formed by the target pattern T5 and accordingly moves the wafer stage to align the mask pattern 6 with the wafer. The blind 40 covers the mask patterns 5, 7, and 8, which are not used in this step and indicated by the crosshatching lines, to selectively expose only the mask pattern 6 and form a pattern corresponding to the mask pattern 6. In this state, the target pattern T6, which is included in the mask pattern 6, forms a target mark on the sensitized layer. The target mark is aligned with the mask pattern 7 used in the next photolithography step.

When exposure is performed in the second metal forming step (step G), the mask pattern 7 of the photomask 30 is used. The image recognizing mechanism detects the target mark formed by the target pattern T6 and accordingly moves the wafer stage to align the mask pattern 7 with the wafer. The blind 40 covers the mask patterns 5, 6, and 8, which are not used in this step and indicated by the cross-hatching lines, to selectively expose only the mask pattern 7 and form a pattern corresponding to the mask pattern 7. In this state, the target pattern T7, which is included in the mask pattern 7, forms a target mark on the sensitized layer. The target mark is aligned with the mask pattern 8 used in the next photolithography step.

When exposure is performed in the pad forming step (step H), the mask pattern 8 of the photomask 30 is used. The image recognizing mechanism detects the target mark formed by the target pattern T7 and accordingly moves the wafer stage to align the mask pattern 8 with the wafer. The blind 40 covers the mask patterns 5, 6, and 7, which are not used in this step and indicated by the cross-hatching lines, to selectively expose only the mask pattern 8 and form a pattern corresponding to the mask pattern 8.

In the preferred embodiment, each of the photomasks 20 and 30 has mask patterns that are successively used during the photolithography process. The eight lithography steps are sequentially performed with the blind 40 covering the mask patterns that are not used in each of the photomasks 20 and 30 to manufacture the desired semiconductor device. It is preferred that the blind 40 have a rectangular cutout portion so that only one region is exposed and that the blind 40 is rotated by 90 degrees at a time to change its covering position.

The preferred embodiment has the advantages described below.

(1) The mask patterns 1 to 4 and the mask patterns 5 to 8 used successively during photolithography are respectively formed in the rectangular regions 11 to 14 and 15 to 18 of the photomasks 20 and 30. Thus, the processing of eight layers in the photolithography process is performed with the two photomasks 20 and 30. In other words, photolithography is efficiently performed just by exchanging the photomasks 20 and 30 once.

The mask patterns 1 to 8 are formed so that the photomasks 20 and 30 are always used oriented in substantially the same direction. Thus, when performing exposure during the photolithography process, the photomasks 20 and 30 do not have to be rotated. This simplifies the photolithography process.

(2) The mask patterns 1 to 8 have the same widths and lengths. Further, the mask patterns 1 to 8 are squares having substantially the same area. The mask patterns 1 to 8 are arranged next to each other on the photomasks 20 and 30, and the photomasks 20 and 30 are substantially squares. Thus, the mask patterns are arranged efficiently on the photomasks 20 and 30. This reduces space that is unused during exposure.

The mask patterns 1 to 8 are formed on the rectangular regions 11 to 18, which have the same shape. This enables the blind 40 to properly cover the mask patterns that are not being used during the photolithography process.

(3) The mask patterns 1 to 8 of the photomasks 20 and 30 include those that are mainly line patterns used to pattern the wiring of the semiconductor device and those that are mainly hole patterns used to pattern the connection holes of the semiconductor device. The typical photolithography process often includes line pattern processing and hole pattern processing, which are performed successively. Thus, the photolithography process for eight layers including the processing of line patterns and the processing of hole patterns is efficiently performed with the two photomasks 20 and 30 by exchanging the photomasks 20 and 30 only once.

(4) The mask patterns 1 to 8 respectively include target patterns T1 to T8 used in the following photolithography step to position the corresponding mask pattern. This enables recognition of the next mask pattern in the photolithography step and improves the mask pattern positioning accuracy during exposure.

It should be apparent to those skilled in the art that the present invention may be embodied in many other specific forms without departing from the spirit or scope of the invention. Particularly, it should be understood that the present invention may be embodied in the following forms.

In the preferred embodiment, four mask patterns are formed on a single photomask, and two photomasks are used to manufacture a semiconductor device. However, the number of patterns formed on a single photomask and the number of photomasks may be changed.

The positions of the photomasks may be changed as long as they are included in the corresponding photomask.

In the photolithography process of the preferred embodiment, the photomasks 20 and 30 are fixed to the exposure apparatus and the wafer is moved to align the mask pattern with the wafer. However, the wafer may be fixed to the exposure apparatus, and the photomask may be moved to align the wafer with the mask pattern. Alternatively, the wafer and the photomask may both be moved to align the wafer and the mask pattern with each other.

In the preferred embodiment, the image recognizing mechanism detects the target mark to accordingly align the mask pattern and the wafer with each other. However, the target pattern formed on the mask pattern may be overlapped with a target mark formed on a wafer to align the mask pattern and the wafer with each other.

The target patterns may be of any shape. For example, the target patterns may be round or linear. The target patterns may also be characters.

The mask patterns do not necessarily have to be squares. The mask patterns are required only to be rectangular so that at least one of the length, width, and area of the mask patterns are the same.

The present examples and embodiments are to be considered as illustrative and not restrictive, and the invention is not to be limited to the details given herein, but may be modified within the scope and equivalence of the appended claims.

What is claimed is:

1. A photomask for use in a plurality of photolithography steps performed to manufacture a semiconductor device having a plurality of layers, the photomask comprising:
a plurality of mask patterns, each used in an associated one of the photolithography steps and corresponding to an associated one of the layers, wherein the mask patterns are arranged so that the photomask is always used oriented in substantially the same direction.

2. The photomask according to claim 1, wherein the mask patterns are arranged on the photomask so that the photomasks are sequentially and successively used during the photolithography steps.

3. The photomask according to claim 1, wherein the mask patters are each formed in one of a plurality of rectangular regions, the rectangular regions being arranged adjacent to one another in the photomask, at least one of a width and length of one of the rectangular regions being substantially the same as at least one of a width and length of another one of the rectangular regions.

4. The photomask according to claim 3, wherein the rectangular regions have the same area.

5. The photomask according to claim 3, wherein each of the rectangular regions is square.

6. The photomask according to claim 1, wherein the mask patterns include a mask pattern mainly configured by a line pattern for patterning wirings of the semiconductor device and a mask pattern mainly configured by a hole pattern for patterning connection holes of the semiconductor device.

7. The photomask according to claim 3, further comprising a target pattern arranged in each rectangular region to form a target mark that is used to position a mask pattern used in a following one of the photolithography steps.

8. The photomask according to claim 7, wherein the target pattern is arranged in a predetermined area of its respective rectangular region.

9. A method for manufacturing a semiconductor device having a plurality of layers, the method comprising:
providing a photomask including a plurality of mask patterns, with each mask pattern corresponding to a different layer of the semiconductor device to be manufactured; and
performing photolithographic processing of each of the layers using the mask pattern of the photomask corresponding to that layer with the photomask arranged each time oriented in a direction that is substantially the same for each layer and exposing only the mask pattern for the layer for which photolithographic processing is currently being performed and covering the other mask patterns.

10. The method according to claim 9, wherein the mask patterns are rectangular regions arranged adjacent to one another, and the step of performing photolithographic processing includes rotating a blind to expose only one of the mask patterns and cover the remaining mask patterns when proceeding from photolithographic processing of one layer to another layer.

11. The method according to claim 10, wherein each rectangular region includes a target pattern for patterning a target mark for aligning the photomask, and the step of performing photolithographic processing includes aligning the target mark patterned for one of the layers with the mask pattern used in a next one of the layers when proceeding from photolithographic processing of one layer to the next layer.

12. The method according to claim 11, wherein the photomask is moved linearly when proceeding from photolithographic processing of one layer to the next layer.

13. The method according to claim 12, wherein the photomask is not rotated when proceeding from photolithographic processing of one layer to the next layer.

14. The method according to claim 11, wherein each of the target patterns is formed in a predetermined area of its respective rectangular region.

15. A photomask for use in performing photolithographic processing to manufacture a semiconductor device having a plurality of layers, the photomask comprising:
a plurality of rectangular regions arranged adjacent to one another;
a plurality of mask patterns, each corresponding to an associated one of the layers; and
a target pattern arranged in each rectangular region for aligning the photomask, wherein each target pattern is arranged in a predetermined area of the rectangular region, the predetermined area being defined at substantially the same position in each of the rectangular regions.

16. A method for manufacturing a semiconductor device using a photomask including a plurality of mask patterns having at least a first mask pattern and a second mask pattern, the method comprising:
exposing the first pattern while covering the other patterns to transcribe the first mask pattern on a semiconductor wafer;
linearly moving the photomask and the semiconductor relative to each other to align the second mask pattern with the semiconductor wafer; and
exposing the second mask pattern while covering the other mask patterns to transcribe the second mask pattern on the semiconductor wafer.

17. The method according to claim 16, wherein the mask patterns each have a plurality of rectangular regions having substantially the same dimensions and arranged adjacent to one another, the method further comprising:
rotating a blind to expose one of the rectangular regions and cover the other rectangular regions.

18. The method according to claim 17, wherein said rotating a blind includes rotating the blind by 90 degrees to expose one of the rectangular regions and cover the other rectangular regions.
